(19) United States
(12) Patent Application Publication
(10) Pub. No.: US 2024/0424946 A1
(43) Pub. Date: Dec. 26, 2024

(54) METHOD FOR EVALUATING ELECTRIC VEHICLE BATTERY STATE USING CHARGING DATA ANALYSIS

(71) Applicant: QUANTUM SOLUTION, INC., Jeju-si (KR)

(72) Inventor: Taeuk CHANG, Seoul (KR)

(73) Assignee: QUANTUM SOLUTION, INC., Jeju-si (KR)

(21) Appl. No.: 18/383,482

(22) Filed: Oct. 25, 2023

Related U.S. Application Data
(63) Continuation of application No. PCT/KR2023/009484, filed on Jul. 5, 2023.

(30) Foreign Application Priority Data
Jun. 21, 2023 (KR) 10-2023-0079477

(51) Int. Cl. B60L 58/12; G01R 31/367; G01R 31/392; G01R 31/396

(52) U.S. Cl. CPC B60L 58/12; G01R 31/367; G01R 31/392; G01R 31/396

(57) ABSTRACT

A method for evaluating an electric vehicle battery state using charging data analysis, includes collecting and analyzing charging data, and classifying battery states for precise diagnosis using a KNN (K-Nearest Neighbor) algorithm in order to diagnose the state, safety, and performance level of an electric vehicle battery using the charging data without disassembling the battery or using an expensive charging/discharging device.

### TECHNICAL FIELD

The present invention relates to a method for evaluating a state of an electric vehicle battery using charging data analysis.

### BACKGROUND ART

The content described below simply provides background information related to the present embodiment and does not constitute prior art.

As demand for electric vehicles (EVs) increases, interest in the performance and lifespan of battery systems is increasing. Methods for evaluating an accurate and efficient battery state are critical to not only ensuring the reliability and safety of electric vehicles, but also optimizing their performance and extending their lifespan.

However, conventional techniques for diagnosing and evaluating a state of an electric vehicle battery have several problems such as invasive procedures, high costs, and limited accuracy. That is, the conventional techniques often involve time-consuming and expensive processes that lack precision and efficiency.

The conventional techniques are invasive and time consuming. Furthermore, the conventional techniques often require disassembling a battery from a vehicle, which results in a time-consuming and labor-intensive procedure. Charging and discharging the battery to evaluate its state further lengthens time necessary for the entire process.

The conventional techniques require an expensive device. For example, the conventional techniques require the use of an expensive, specialized device to charge and discharge the battery, which results in an additional cost for a diagnostic process.

The conventional techniques have limited accuracy. For example, the conventional techniques such current integration method includes a process of measuring voltage, current and temperature values under fixed conditions (for example, at a constant current and a fixed temperature of 25° C.). However, the above-mentioned approaches limit the accuracy and precision of battery state evaluation.

In addition, the conventional techniques are not capable of real-time monitoring. That is, the conventional techniques cannot monitor the state, safety, and performance levels of a battery in real time, which hinders proactive decision-making and management of the battery state.

In considering such limitations of the conventional techniques, it is desirable to provide an efficient, cost-effective, and accurate technique for evaluating the state, safety, and performance of an electric vehicle battery.

### DISCLOSURE

### Technical Problem

To solve the above problems, it is an object of the present invention to provide a method for evaluating an electric vehicle battery state using charging data analysis, capable of collecting and analyzing charging data and classifying battery states for precise diagnosis using a KNN (K-Nearest Neighbor) algorithm in order to diagnose the state, safety, and performance level of an electric vehicle battery using the charging data without disassembling the battery or using an expensive charging/discharging device.

### Technical Solution

According to one aspect of the present embodiment, there is provided a method for evaluating an electric vehicle battery state, including: a data collection of step collecting, as charging data, data exchanged during a charging process from a charger to an electric vehicle; a data analysis step of extracting feature information from the charging data and applying the KNN algorithm to each of a plurality of items included in the feature information to generate level analysis data for each item; a comparison and diagnosis step of comparing the level analysis data for each item with a reference data set having an average value for the same type of electric vehicles to generate a comparison result, recognizing that an abnormality has occurred in a case where a difference exceeding a preset threshold occurs on the basis of the comparison result, and generating battery state change information based on the comparison result; a real-time monitoring step of repeating a process of continuously collecting the charging data and cumulatively reflecting the level analysis data for each item in a concerned type of electric vehicle; and a battery state transmission step of transmitting the battery state change information to the electric vehicle via the charger.

### Advantageous Effects

According to the present invention, it is possible to collect and analyze charging data, and classify battery states for precise diagnosis using the KNN algorithm to diagnose the state, safety, and performance level of an electric vehicle battery using the charging data without disassembling the battery or using an expensive charging/discharging device.

According to the present invention, it is possible to achieve efficiency improvement and cost reduction. By utilizing the charging data and eliminating the need for battery disassembly or an additional device, it is possible to simplify the battery state evaluating process to save cost and time.

According to the present invention, is it possible to improve the accuracy and reliability of battery evaluation. By focusing on the charging data and applying the KNN algorithm, it is possible to precisely diagnose the battery state, safety, and performance level.

According to the present invention, it is possible to monitor the battery in real time, and detect the state of the battery early. Through continuous collection and analysis of the charging data, it is possible to monitor the state of the battery in real time to detect potential problems early.

According to the present invention, it is possible to make data-based decision in evaluating the battery. By providing classified and precise battery state evaluation, it is possible for electric vehicle owners and service providers to make information-based decisions regarding battery maintenance, replacement and management.

According to the present invention, as the improved accuracy and efficiency improves the battery performance, safety, and lifespan, it is possible to have a positive influence on the entire electric vehicle industry including manufacturers, service providers and end users.

### DESCRIPTION OF DRAWINGS

The above and other objects, features and other advantages of the present invention will be more clearly understood from the following detailed description taken in conjunction with the accompanying drawings, in which:

FIG. 1 is a diagram showing an electric vehicle battery state evaluating system using charging data analysis according to an embodiment of the invention;

FIG. 2 is a diagram showing an electric vehicle battery state evaluating device according to an embodiment of the invention; and

FIGS. 3A, 3B, and 3C are flowcharts illustrating a method for evaluating a state of an electric vehicle battery using charging data analysis according to an embodiment of the invention.

### BEST MODE

Hereinafter, this embodiment will be described in detail with reference to the attached drawings.

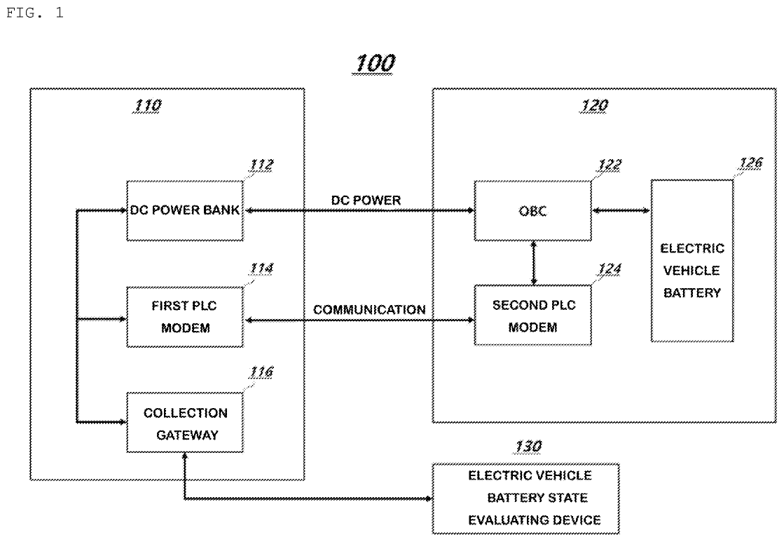

FIG. 1 is a diagram showing an electric vehicle battery state evaluating system using charging data analysis according to an embodiment of the invention.

An electric vehicle battery state evaluating system 100 according to the embodiment includes a charger 110, an electric vehicle 120, and an electric vehicle battery state evaluating device 130. Components included in the electric vehicle battery state evaluating system 100 are not necessarily limiting.

When charging the electric vehicle 120, the charger 110 collects charging data including voltage, current, and temperature values during the charging process. When charging the electric vehicle 120, the charger 110 performs communication to collect charging data including an electric vehicle communication controller identifier (EVCCID), a maximum voltage, and a necessary charging power. The charger 110 transmits the charging data to the electric vehicle battery state evaluating device 130.

The charger 110 includes a DC power bank 112, a first power line communication (PLC) modem 114, and a collection gateway 116.

The DC power bank 112 is connected to an on-board-charger (OBC) 122 of the electric vehicle 120 and supplies power thereto.

The first PLC modem 114 supports charging of the electric vehicle 120 using power line communication. The first PLC modem 114 integrally operates power supply, control, and various additional service information between the charger 110 and the electric vehicle 120. The first PLC modem 114 provides high-speed power line communication between the electric vehicle 120 and the charger 110 using a control pilot line of a charging cable for charging the electric vehicle 120.

The first PLC modem 114 includes a control box integrated with the charging cable based on the power line communication. When charging the electric vehicle 120 with the DC power bank 112, the first PLC modem 114 receives a safety state, battery information, and the like of the electric vehicle 120 from a second PLC modem 124.

The first PLC modem 114 performs communication with the second PLC modem 124 of the electric vehicle 120. The first PLC modem 114 exchanges, through communication with the second PLC modem 124, information such as the electric vehicle communication controller identifier (EVCCID), the maximum voltage, and the necessary charging power of the electric vehicle 120, between the electric vehicle 120 and the charger 110.

The first PLC modem 114 communicates with the second PLC modem 124 to obtain charging data including the electric vehicle communication controller identifier (EVCCID), the maximum voltage, and the necessary charging power, and transmits the result to the collection gateway 116.

The collection gateway 116 collects the charging data from the first PLC modem 114. When supplying power to the electric vehicle 120 using the DC power bank 112, the collection gateway 116 collects charging data including the electric vehicle communication controller identifier (EVCCID), the maximum voltage, and the necessary charging power from the PLC modem 114. The collection gateway 116 transmits the charging data to the electric vehicle battery state evaluating device 130.

The collection gateway 116 exchanges information between the first PLC modem 114 of the charger 110 and the second PLC modem 124 of the electric vehicle 120 to collect the charging data during the charging process on the basis of the charging voltage and current values.

The collection gateway 116 measures the charging voltage and current values using the DC power bank 112. The collection gateway 116 collects data from each of the DC power bank 112 and the first PLC modem 114, and then transmits the result to the electric vehicle battery state evaluating device 130.

The electric vehicle 120 includes the on-board-charger (OBC) 122, the second power line communication (PLC) modem 124, and an electric vehicle battery 126.

The OBC 122 is mounted on the electric vehicle 120 so as to directly charge the electric vehicle battery 126 from a utility line power source. The OBC 122 receives power from the DC power bank 112 of the charger 110 to charge the electric vehicle battery 126.

The second PLC modem 124 supports charging of the electric vehicle 120 using power line communication. The second PLC modem 124 performs communication with the first PLC modem 114 of the charger 110. The second PLC modem 124 integrally operates power supply, control, and various additional service information between the charger 110 and the electric vehicle 120. The second PLC modem 124 provides high-speed power line communication between the electric vehicle 120 and the charger 110 using a control pilot line of the charging cable for charging the electric vehicle 120.

The second PLC modem 124 includes a control box integrated with the charging cable based on the power line communication. The second PLC modem 124 exchanges, through communication with the first PLC modem 114, information such as the electric vehicle communication controller identifier (EVCCID), the maximum voltage, and the necessary charging power for the electric vehicle 120, between the electric vehicle 120 and the charger 110. When receiving power from the DC power bank 112 to the OBC 122, the second PLC modem 124 transmits the safety state and battery information of the electric vehicle 120 to the first PLC modem 114.

The electric vehicle battery 126 is provided in the electric vehicle 120 and is charged by power supplied from the OBC 122.

The electric vehicle battery state evaluating device 130 may be implemented inside or outside the charger 110. The electric vehicle battery state evaluating device 130 is implemented separately outside the charger 110, collects charging data from the collection gateways 116 within the plurality of chargers 110, and then, transmits the analysis result to the electric vehicle 120 through the collection gateways 116 of the chargers 110.

The electric vehicle battery state evaluating device 130 collects the charging data in a non-invasive manner during the charging process without disassembling the battery to evaluate the state of the battery of the electric vehicle.

The electric vehicle battery state evaluating device 130 reliably diagnoses the state, safety, and performance level of the electric vehicle battery 126 on the basis of the charging data collected from the charger 110. The electric vehicle battery state evaluating device 130 diagnoses the state of the battery using the KNN algorithm, and then, additionally applies LSTM (Long Short Term Memory), CNN (Convolution Neural Network), RNN (Recurrent Neural Network), or the like to accurately diagnose the state of the battery. The electric vehicle battery state evaluating device 130 continuously collects and analyzes data to monitor the state of the battery in real time.

The electric vehicle battery state evaluating device 130 provides an initial accuracy of approximately 90% in analyzing charging data of a single vehicle. The electric vehicle battery state evaluating device 130 increases the accuracy to 95% or more in a case where more than 100 charging data points are accumulated for the same vehicle to evaluate the state of the battery.

Unlike general chargers, the electric vehicle battery state evaluating device 130 utilizes unique characteristics of the charger that can charge the battery with constant current. The charger 110 communicates with the electric vehicle 120 to adjust the charging amount and monitor the state of charge (SoC) of the battery. The electric vehicle battery state evaluating device 130 analyzes the battery state on the basis of the charging data obtained through communication between the charger 110 and the electric vehicle 120.

The electric vehicle battery state evaluating device 130 continuously monitors the state of the battery without a separate expensive device or battery disassembly on the basis of the electric vehicle communication controller identifier (EVCCID) of the electric vehicle 120 and the charging data exchanged between the electric vehicle 120 and the charger 110. The electric vehicle battery state evaluating device 130 accurately and precisely evaluates the state of the battery using a data analysis technique.

The electric vehicle battery state evaluating device 130 evaluates the battery state, safety, and performance level of the electric vehicle (EV) using the charging data.

The electric vehicle battery state evaluating device 130 analyzes the charging data obtained from the charger 110. The electric vehicle battery state evaluating device 130 generates analysis results obtained by analyzing the charging data using the KNN algorithm. The electric vehicle battery state evaluating device 130 accurately and precisely diagnoses the battery state, safety, and performance level using the analysis results. The electric vehicle battery state evaluating device 130 groups voltage values according to the amount of change at a specific point in time into a plurality of levels (for example, A, B, C, and D levels), and then, diagnoses the battery state from 0% to 100% within the respective levels.

The electric vehicle battery state evaluating device 130 compares the analysis data with a reference data set including an average value for the same type of vehicles. In a case where a difference corresponding to abnormality is detected during the comparison process, the electric vehicle battery state evaluating device 130 generates and outputs change results in the battery state and safety state. The electric vehicle battery state evaluating device 130 provides a comprehensive evaluation of the battery state by comparing the change results with those of other vehicles of the same type.

The electric vehicle battery state evaluating device 130 continuously collects and analyzes the charging data from the charger 110 to monitor the battery state, safety, and performance levels in real time. The electric vehicle battery state evaluating device 130 accumulates a preset number of (for example, 100 or more) pieces of charging data for the same vehicle to improve the accuracy of battery state diagnosis.

The electric vehicle battery state evaluating device 130 outputs the battery state evaluation result to a user interface or dashboard within the electric vehicle 120 via the charger 110. During charging, the electric vehicle 120 outputs the battery state evaluation result received from the electric vehicle battery state evaluating device 130 via the charger 110. The user of the electric vehicle 120 may make decisions about maintenance, replacement, or management of the battery on the basis of the battery state evaluation result output through the user interface or dashboard.

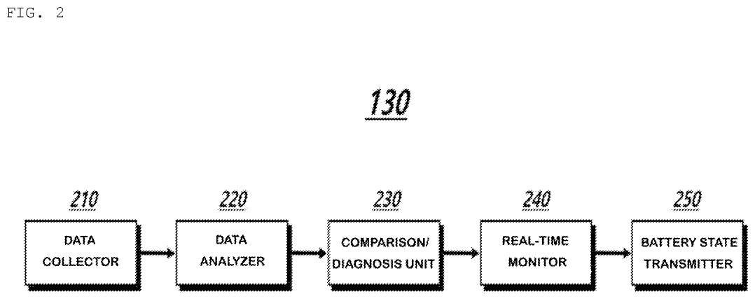

FIG. 2 is a diagram showing an electric vehicle battery state evaluating device according to an embodiment of the invention.

The electric vehicle battery state evaluating device 130 evaluates the battery state, safety, and performance level of the electric vehicle 120 on the basis of the charging data obtained from the collection gateway 116.

The electric vehicle battery state evaluating device 130 collects the battery charging data during charging. The electric vehicle battery state evaluating device 130 generates analysis data obtained by diagnosing the battery state, safety, and performance level on the basis of the collected charging data using the KNN algorithm. The electric vehicle battery state evaluating device 130 compares the analysis data with the reference data set to identify the difference corresponding to abnormality.

The electric vehicle battery state evaluating device 130 transmits the analysis data back to the electric vehicle 120 via the collection gateway 116 of the charger 110. The electric vehicle 120 outputs information related to the battery maintenance, replacement, or management received from the electric vehicle battery state evaluating device 130 via the charger 110.

The electric vehicle battery state evaluating device 130 provides the analysis data to the electric vehicle 120 without connecting an additional device or disassembling the battery while the electric vehicle 120 is connected to the charger 110 for charging. The electric vehicle battery state evaluating device 130 accumulates a preset number of (for example, 100 or more) charging data points for the same vehicle to improve the accuracy of battery state diagnosis. The electric vehicle battery state evaluating device 130 continuously collects and analyzes the charging data to monitor the battery state, safety, and performance level in real time.

The electric vehicle battery state evaluating device 130 according to this embodiment includes a data collector 210, a data analyzer 220, a comparison/diagnosis unit 230, a real-time monitor 240, and a battery state transmitter 250. Components included in the electric vehicle battery state evaluating device 130 are not necessarily limiting.

The respective components included in the electric vehicle battery state evaluating device 130 are connected to a communication path connecting software modules or hardware modules within the device to interoperate with each other. These components perform communication using one or more communication buses or signal lines.

Each component of the electric vehicle battery state evaluating device 130 shown in FIG. 2 refers to a unit that performs at least one function or operation, and may be implemented as a software module, a hardware module, or a combination of software and hardware.

The data collector 210 collects, as charging data, data exchanged during the charging process between the charger 110 and the electric vehicle 120.

The data collector 210 collects charging data including one or more of the electric vehicle communication controller identifier (EVCCID), the maximum voltage, and the necessary charging power for the electric vehicle 120 from the collection gateway 116 of the charger 110.

When supplying power to the electric vehicle 120 using the DC power bank 112 of the charger 110, the data collector 210 collects, as the charging data, date exchanged between the charger 110 and the electric vehicle 120 from the collection gateway 116 of the charger 110 using the first PLC modem 114.

The data analyzer 220 extracts feature information from the charging data. The data analyzer 220 applies the KNN algorithm to a plurality of items (battery voltage, charging time, related level) included in the feature information to generate level analysis data for each item.

The data analyzer 220 extracts feature information such as a battery voltage and a charging time from the charging data. The data analyzer 220 applies the KNN algorithm to each battery voltage and each charging time to group the respective items according to the amount of change at a specific point in time into a plurality of levels (A, B, C, and D levels). The data analyzer 220 diagnoses the battery state from 0% to 100% within the respective levels to diagnose the level for each item.

The data analyzer 220 performs pre-processing for removing missing or inconsistent values among the electric vehicle communication controller identifier (EVCCID), the maximum voltage, and the necessary charging power included in the charging data to generate pre-processed data.

The data analyzer 220 extracts feature information (battery voltage, charging time, and related level) from the pre-processed data.

The data analyzer 220 performs maximum-minimum normalization on all items included in the feature information (battery voltage, charging time, and related level) to generate maximum-minimum normalization data.

The data analyzer 220 divides the maximum-minimum normalization data into a training set and a test set at a preset ratio. When dividing the maximum-minimum normalization data, the data analyzer 220 divides the data set into k (at least 10) folds of the same size.

The data analyzer 220 sets a range of k values (k is an integer of 1 to 100) in the KNN algorithm. The data analyzer 220 performs k-fold cross-validation for the test set (20%) on the basis of the range of the k values.

When performing the k-fold cross-validation, the data analyzer 220 determines whether a difference between a result value (20% value) output by performing a test based on the test set (20%) and a result value (expected value) output by applying the KNN algorithm falls within a preset range.

The data analyzer 220 trains the KNN algorithm with the training set (80%) divided from the maximum-minimum normalization data. The data analyzer 220 uses a fold as the test set and uses the remaining k−1 folds as the training set, for the respective folds having the same size of data set obtained by dividing the maximum-minimum normalization data.

The data analyzer 220 normalizes the battery voltage and the charging time in both the training set and the test set on the basis of the maximum-minimum normalization data. The data analyzer 220 applies the KNN algorithm using each k value in a range specified in the test set and the training set. The data analyzer 220 calculates performance indicators (accuracy, precision, recall, F1 score) for each k value.

The data analyzer 220 calculates an average performance by accumulating performance indicators for each k value for the same type of electric vehicles. The data analyzer 220 reflects the average performance in a reference data set having an average value for the same type of electric vehicles.

The data analyzer 220 selects an optimal k value that provides the best performance by comparing a k value in a condition table of the KNN algorithm with the k value (new k value).

The data analyzer 220 retrains the KNN algorithm with the optimal k value in the entire training sets (entire data sets).

The data analyzer 220 calculates distances between each data point in the test set (20%) divided from the maximum-minimum normalization data and all data points in the training set within the KNN algorithm. The data analyzer 220 sorts the calculated distances in an ascending order and selects the k nearest neighbors. The data analyzer 220 determines a plurality of levels among the k nearest neighbors. The data analyzer 220 assigns the determined levels to test data points and performs nearest neighbor (KNN) model evaluation on the test set.

The data analyzer 220 determines whether fine adjustment is necessary on the basis of a model evaluation result of the nearest neighbor (KNN) model evaluation. In a case where the fine adjustment is not necessary, the data analyzer 220 distributes the nearest neighbor (KNN) model, registers a new k value optimized in the distributed nearest neighbor (KNN) model, and then classifies new data points into the respective levels on the basis of the battery voltage and charging time, using the new k value.

The data analyzer 220 determines whether the fine adjustment is necessary on the basis of the model evaluation result. In a case where the fine adjustment is not necessary, the data analyzer 220 classifies new data points into the respective levels on the basis of the battery voltage and charging time using the pre-selected k value after hyper parameter/pre-processing adjustment.

The comparison/diagnosis unit 230 generates a comparison result obtained by comparing the level analysis data for each item with a reference data set having an average value for the same type of electric vehicles. As a result of the comparison, in a case where a difference exceeding a preset threshold occurs, the comparison/diagnosis unit 230 recognizes that an abnormality has occurred, and generates battery state change information on the basis of the comparison result.

The comparison/diagnosis unit 230 extracts the reference data set having the average value for the same type of electric vehicles as the electric vehicle corresponding to the level analysis data for each item. The comparison/diagnosis unit 230 compares the level analysis data for each item with the reference data set, and recognizes that an abnormality has occurred in a case where a difference between the reference data set and the level analysis data for each item exceeds a preset threshold. The comparison/diagnosis unit 230 generates battery state change information on the basis of the comparison result between the level analysis data for each item and the reference data set.

The real-time monitor 240 continuously collects charging data and repeats the process of cumulatively reflecting the generated level analysis data for each item to a concerned type of electric vehicle.

The real-time monitor 240 continuously collects charging data, accumulates a preset number of (for example, 100 or more) pieces of data for the same type of electric vehicles, and reflects an average value thereof in the reference data set.

The battery state transmitter 250 transmits battery state change information to the electric vehicle 120 via the charger 110. The battery state transmitter 250 outputs the battery state change information to a user interface or dashboard within the electric vehicle 120 via the charger 110.

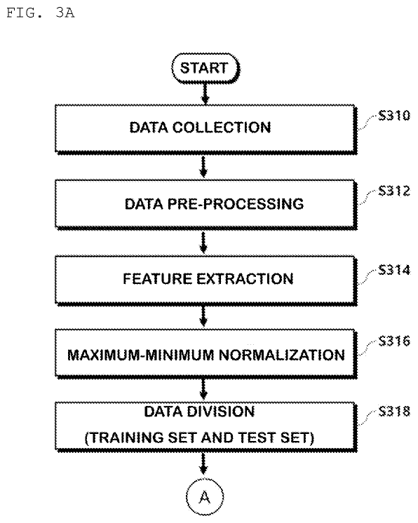

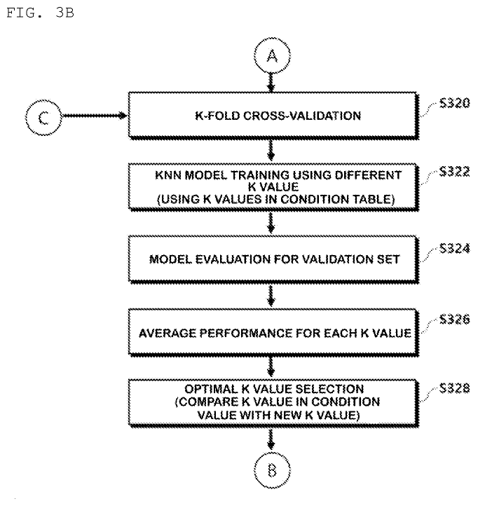

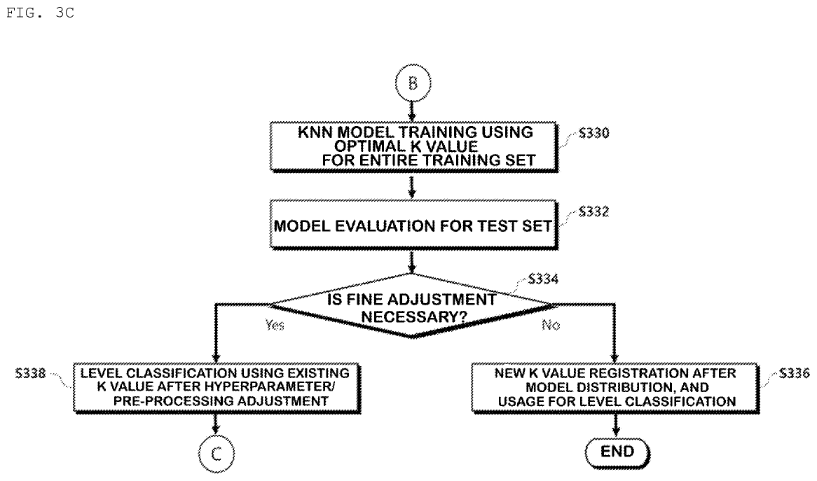

FIGS. 3A, 3B, and 3C are flowcharts illustrating an electric vehicle battery state evaluating method using charging data analysis according to an embodiment of the invention.

The electric vehicle battery state evaluating device 130 collects charging data from the collection gateway 116 while the charger 110 is being connected to the electric vehicle 120 to charge the electric vehicle 120 (S310).

In step S310, while the electric vehicle battery 126 of the electric vehicle 120 is being charged for a preset time (for example, 20 minutes), the electric vehicle battery state evaluating device 130 collects charging data (communication controller identifier (EVCCID), maximum voltage, necessary charging power, and the like) exchanged between the charger 110 and the electric vehicle 120.

The electric vehicle battery state evaluating device 130 performs pre-processing on the collected charging data to generate pre-processed data (S312).

In step S312, the electric vehicle battery state evaluating device 130 generates the pre-processed data by removing missing or inconsistent values among the electric vehicle communication controller identifier (EVCCID), the maximum voltage, and the necessary charging power included in the charging data collected for a preset time (for example, 20 minutes).

The electric vehicle battery state evaluating device 130 extracts feature information (battery voltages, charging times, and related levels) from the pre-processed data (S314).

In step S314, the electric vehicle battery state evaluating device 130 extracts the battery voltages, the charging times, and the related levels (100 to 90, 89 to 80, 79 to 70, or 69 or less) from each data point of the pre-processed data.

The electric vehicle battery state evaluating device 130 performs maximum-minimum normalization on all items included in the feature information (battery voltages, charging times, related levels) extracted from the pre-processed data using [Equation 1] to generate maximum-minimum normalization data (S316).

$${Normalized}_{value} = \frac{( {Current}_{value} - {Min}_{value} )}{( {Max}_{value} - {Min}_{value} )} \qquad [ Equation 1 ]$$

In step S316, the maximum-minimum normalization is performed to determine the maximum and minimum values of individually collected data and to use the maximum and minimum values for diagnosis.

For example, for convenience of description, it is assumed that the first charging data has data from 200V to 420V, and the second data has data from 230V to 400V.

In a case where 220V to 420V is determined as the maximum-minimum value, the electric vehicle battery state evaluating device 130 modifies the minimum value of the first data to 220V to 420V and modifies the minimum value of the second data to 220V to 400V. The electric vehicle battery state evaluating device 130 creates a value of 400V to 420V using transfer learning and agumentation, or determines that the second data is invalid. As described above, the electric vehicle battery state evaluating device 130 performs the maximum-minimum normalization on an individual data set.

In other words, the electric vehicle battery state evaluating device 130 adjusts the data to the same range to speed up the operation of the KNN algorithm.

In step S316, the electric vehicle battery state evaluating device 130 generates maximum-minimum normalization data for each data point on the basis of current values of the feature information (battery voltages, charging times, and related levels) and the maximum and minimum values for the feature information (battery voltages, charging times, and related levels) of the entire data set.

The electric vehicle battery state evaluating device 130 performs data division (training set and test set) at a preset ratio for the maximum-minimum normalization data (S318).

In step S318, in dividing the maximum-minimum normalization data, the electric vehicle battery state evaluating device 130 divides the data set into k folds of the same size (10 or more divisions).

In step S318, the electric vehicle battery state evaluating device 130 divides the maximum-minimum normalization data into the training set (for example, 80%) and the test set (for example, 20%).

Then, the electric vehicle battery state evaluating device 130 applies the KNN algorithm using the training set (for example, 80%) and the test set (for example, 20%).

The KNN (K-Nearest Neighbors) algorithm is an algorithm that determines which of a plurality of groups (neighbors) for which a correct answer is known is more similar to an input value.

Here, k represents the number of ‘neighbors’. The KNN algorithm calculates a distance between a new arbitrary input value and each neighbor. The KNN algorithm finds the nearest neighbors on the basis of the calculated distances. The KNN algorithm determines that the arbitrary input value corresponds to a neighbor with the closest distance. The KNN algorithm secures a lot of neighbors, and then determines which neighbor a new input value corresponds to. The electric vehicle battery state evaluating device 130 generates neighbors of 91%, 92% or the like, captures characteristics of a new input data set, and then determines which neighbor is closer.

The electric vehicle battery state evaluating device 130 sets a range of k values for test (k is an integer of 1 to 100) in order to select the k value in the KNN algorithm. The electric vehicle battery state evaluating device 130 performs k-fold cross-validation on an input test set (20%) on the basis of the range of k values (k is an integer of 1 to 100) (S320).

In step S320, the electric vehicle battery state evaluating device 130 divides the maximum-minimum normalization data into the training set (80%) and the test set (20%), performs a test on the basis of the test set (20%), and then determines whether an output result value (20% value) is similar to an expected value output by applying the KNN algorithm.

In other words, in a case where a result value of arbitrary input data (20%) is output, since the result value is not reliable, the electric vehicle battery state evaluating device 130 ensures the reliability of an engine by comparing the result with an expected output value from input of known data (20%).

The electric vehicle battery state evaluating device 130 divides the maximum-minimum normalization data into the training set (80%) and the test set (20%), and then, trains the training set (80%) with the KNN algorithm to learn the engine (S322).

In step S322, the electric vehicle battery state evaluating device 130 uses, for respective folds having the same size in the data set obtained by dividing the maximum-minimum normalization data, a fold as the test set and the remaining k−1 folds as the training set.

The electric vehicle battery state evaluating device 130 divides the data set into k folds of the same size. Here, the number of folds, that is, k is 10 or more. Among the respective folds, the electric vehicle battery state evaluating device 130 uses a fold as the test set and uses the remaining k−1 folds as the training set. The electric vehicle battery state evaluating device 130 normalizes the battery voltages and the charging times in both the training set and the test set on the basis of the maximum-minimum normalization data. The electric vehicle battery state evaluating device 130 applies the KNN algorithm using each k value in the range specified in the test set and the training set. The electric vehicle battery state evaluating device 130 calculates performance indicators (accuracy, precision, recall, and F1 score) for each k value (S324).

The electric vehicle battery state evaluating device 130 calculates an average performance for each k value (S326). In step S326, the electric vehicle battery state evaluating device 130 calculates the average performance by accumulating the performance indicators for each k value for the same type of electric vehicles, and reflects the average performance in a reference data set having an average value for the same type of electric vehicles.

The electric vehicle battery state evaluating device 130 compares the average performance indicators for the respective k values to select an optimal k value for providing the best performance (S328).

In step S328, the electric vehicle battery state evaluating device 130 selects the optimal k value for providing the best performance by comparing the k value in the condition table of the KNN algorithm with a new k value.

In step S328, the electric vehicle battery state evaluating device 130 considers balance between the complexity of the model and the ability to generalize to new data. In a case where the k value is small, overfitting may occur, and in a case where the k value is large, an oversimplified model may be created.

The electric vehicle battery state evaluating device 130 retrains the KNN model with the optimal k value from the entire training set (entire data set) (S330).

In step S330, the electric vehicle battery state evaluating device 130 applies maximum-minimum normalization to the battery voltages and the charging times, and then uses the selected k value for classification.

The electric vehicle battery state evaluating device 130 performs model evaluation on the test set (S322).

The electric vehicle battery state evaluating device 130 calculates, for each data point in the test set, a Euclidean distance between a concerned data point and all data points in the training set. The electric vehicle battery state evaluating device 130 sorts the calculated distances in an ascending order, and selects k nearest neighbors. The electric vehicle battery state evaluating device 130 determines a plurality of levels from among the k nearest neighbors, and assigns the levels to test data points. Then, the electric vehicle battery state evaluating device 130 repeats the distance calculation, neighbor selection, and data point allocation for all the data points in the test set.

The electric vehicle battery state evaluating device 130 determines whether fine adjustment is necessary on the basis of the model evaluation result (S324).

As a result of the determination in step S324, in a case where the fine adjustment is not necessary, the electric vehicle battery state evaluating device 130 registers a new k value after distributing the model, and uses the result for classification (S336).

In step S336, in a case where the fine adjustment is not necessary, the electric vehicle battery state evaluating device 130 distributes the nearest neighbor (KNN) model, registers a new k value optimized in the distributed nearest neighbor (KNN) model, and then classifies new data points into each level on the basis of the battery voltage and charging time using the new k value.

In a case where the fine adjustment is not necessary, the electric vehicle battery state evaluating device 130 implements the KNN algorithm. The electric vehicle battery state evaluating device 130 calculates, for each data point in the test set, the Euclidean distance between the data point and all the data points in the training set. The electric vehicle battery state evaluating device 130 sorts the calculated distances in an ascending order, and selects k nearest neighbors. The electric vehicle battery state evaluating device 130 determines a plurality of levels from among the k nearest neighbors, and assigns the levels to test data points to perform model evaluation for the test set. Then, the electric vehicle battery state evaluating device 130 repeats the distance calculation, neighbor selection, and data point allocation for all the data points in the test set.

The electric vehicle battery state evaluating device 130 applies the learned KNN model. The electric vehicle battery state evaluating device 130 optimizes the k value of the used KNN model, and classifies new data points into each level on the basis of the battery voltage and the charging time using the k value.

The electric vehicle battery state evaluating device 130 configures the optimal k value for each vehicle, configures the k values for each year and each SoH of the same type of electric vehicles into a condition table, and then finds and applies an appropriate k value on the basis of vehicle information.

As a result of the determination in step S324, in a case where the fine adjustment is necessary, the electric vehicle battery state evaluating device 130 adjusts the hyper parameter/pre-processing, and then performs the level classification using the existing k value (S338).

In step S338, in a case where the fine adjustment is not necessary, the electric vehicle battery state evaluating device 130 adjusts the hyper parameter/pre-processing, and then classifies new data points into each level on the basis of the battery voltage and the charging time using the pre-selected k value.

In FIG. 3, an example in which steps S310 to S338 are sequentially executed is shown, but the invention is not limited thereto. For example, the order of the steps shown in FIG. 3 may be modified, or two or more of the steps may be executed in parallel.

The above-described method for evaluating the state of the electric vehicle battery using charging data analysis according to the present embodiment shown in FIG. 3 may be implemented as a program, and the program may be recorded on a computer-readable recording medium. The computer-readable recording medium on which the program is recorded includes all types of recording devices that store data that is readable by a computer system.

The above description is merely an illustrative explanation of the technical idea of the present embodiment, and those skilled in the art will be able to make various modifications and variations without departing from the essential characteristics of the present embodiment. Accordingly, the present embodiments are not intended to limit the technical idea of the present invention, and the scope of the technical idea of the present embodiment is not limited by these examples. The scope of the invention should be interpreted in accordance with claims below, and all technical ideas within the equivalent scope should be interpreted as being included in the scope of the invention.

1. A method for evaluating an electric vehicle battery state, comprising:
a data collection step of collecting, as charging data, data exchanged during a charging process from a charger to an electric vehicle;
a data analysis step of extracting feature information from the charging data and applying a nearest neighbor algorithm to each of a plurality of items included in the feature information to generate level analysis data for each item;
a comparison and diagnosis step of comparing the level analysis data for each item with a reference data set having an average value for the same type of electric vehicles to generate a comparison result, recognizing that an abnormality has occurred in a case where a difference exceeding a preset threshold occurs on the basis of the comparison result, and generating battery state change information based on the comparison result;
a real-time monitoring step of repeating a process of continuously collecting the charging data and cumulatively reflecting the level analysis data for each item in a concerned type of electric vehicle; and
a battery state transmission step of transmitting the battery state change information to the electric vehicle via the charger.

2. The method according to claim 1, wherein the data collection step includes collecting the charging data including at least one of a communication controller identifier (EVCCID), a maximum voltage, and a necessary charging power for the electric vehicle from a collection gateway of the charger.

3. The method according to claim 1, wherein the data analysis step includes extracting the feature information including a battery voltage and a charging time from the charging data, applying the nearest neighbor algorithm to each battery voltage and each charging time to group the respective items into a plurality of levels (A, B, C, and D levels) according to the amount of change at a specific point in time, and diagnosing the battery state from 0% to 100% within the respective levels to diagnose the level of each item.

4. The method according to claim 1, wherein the comparison and diagnosis step includes extracting the reference data set having the average value for the same type of electric vehicles as the electric vehicle corresponding to the level analysis data for each item, comparing the level analysis data for each item with the reference data set, recognizing that the abnormality has occurred in a case where the difference between the reference data set and the level analysis data for each item exceeds the preset threshold, and generating battery state change information based on the comparison result between the level analysis data for each item and the reference data set.

5. The method according to claim 1, wherein the real-time monitoring step includes continuously collecting the charging data, accumulating a preset number of pieces of data for the same type of electric vehicles to calculate an average value, and reflecting the average value in the reference data set.

6. The method according to claim 1, wherein the battery state transmitting step includes outputting the battery state change information to a user interface or dashboard within the electric vehicle via the charger.

7. The method according to claim 1, wherein the data collection step includes receiving, in supplying power to the electric vehicle using a DC power bank of the charger, the charging data obtained by collecting data exchanged between the charger and the electric vehicle from the collection gateway of the charger using a first PLC modem.

8. The method according to claim 1, wherein the data analysis step includes performing pre-processing for removing missing or inconsistent values among a communication controller identifier (EVCCID), a maximum voltage, and a necessary charging power included in the charging data.
